(19) United States
(12) Patent Application Publication
(10) Pub. No.: US 2026/0020490 A1
(43) Pub. Date: Jan. 15, 2026

(54) PRODUCTION METHOD FOR SOLAR BATTERY

(71) Applicant: KANEKA CORPORATION, Osaka (JP)

(72) Inventor: Ryota MISHIMA, Settsu-shi (JP)

(73) Assignee: KANEKA CORPORATION, Osaka (JP)

(21) Appl. No.: 19/338,650

(22) Filed: Sep. 24, 2025

Related U.S. Application Data
(63) Continuation of application No. PCT/JP2024/008664, filed on Mar. 7, 2024.

(30) Foreign Application Priority Data
Mar. 28, 2023 (JP) 2023-050874

(51) Int. Cl. H10K 77/10; H10K 30/50; H10K 85/50

(52) U.S. Cl. CPC H10K 77/10; H10K 30/50; H10K 85/50

(57) ABSTRACT

A production method for a solar battery includes a step for applying a varnish to form a base material layer on the surface of a support substrate that has a structure of recesses and protrusions formed at the surface thereof, a step for forming a photoelectric conversion structure on the base material layer, and a step for peeling the base material layer from the support substrate.

### CROSS-REFERENCE TO RELATED APPLICATIONS

This application claims benefit of priority to International Patent Application No. PCT/JP2024/008664, filed Mar. 7, 2024, and to Japanese Patent Application No. 2023-050874, filed Mar. 28, 2023, the entire contents of each are incorporated herein by reference.

### BACKGROUND

### Technical Field

The present disclosure relates to a method for manufacturing a solar cell.

### Background Art

It is known that a flexible solar cell is produced by forming a photoelectric conversion layer on a resin film. In a case where the resin film is bent or made wavy at the time of forming the photoelectric conversion layer, the photoelectric conversion layer cannot be formed with high precision. To address this, for example, PCT International Publication No. WO 2015/147106 proposes a method in which a precursor is applied to a support substrate, a resin film tightly adhering to the support substrate is formed by heating, an electrode layer, a photoelectric conversion layer, and the like are further formed over the resin film, and thereafter, the resin film is peeled off from the support substrate.

It is also known that the formation of a concave-convex structure on the light-receiving surface of a solar cell can reduce light reflection and improve photoelectric conversion efficiency. For example, Japanese Unexamined Patent Application, Publication No. 2010-183000 discloses that a photocurable resin composition is applied to a transparent substrate film, the composition is pressed onto a mold, the composition is cured by irradiation with UV light from the back surface of the transparent substrate film, and thereafter, the mold is removed, thereby obtaining a film substrate adapted for a thin-film solar cell and having a fine concave-convex shapes constituted of regular polygonal pyramids spread without gaps. An electrode layer, a photoelectric conversion layer, and a transparent electrode layer are stacked over the concave-convex shaped surface of the film substrate for thin-film solar cell, thereby producing a solar cell.

### SUMMARY

In the case where a photoelectric conversion structure is formed on a film having a concave-convex structure as in Japanese Unexamined Patent Application, Publication No. 2010-183000, since a resin film may be warped or made wavy, it is impractical to employ a method of forming a thin layer by the application of a material. It is conceivable to employ a method of attaching a film with a concave-convex structure formed thereon after forming a photoelectric conversion layer and the like, but there may be disadvantages such as a decrease in photoelectric conversion efficiency and an increase in manufacturing cost due to an adhesive layer or the like that is provided in addition to the film with the concave-convex structure.

In view of the circumstances described above, the present disclosure provides a method capable of manufacturing a solar cell having high photoelectric conversion efficiency.

A method for manufacturing a solar cell according to one aspect of the present disclosure includes forming a base material layer on a surface of a support substrate by applying a varnish, the surface having a concave-convex structure; forming a photoelectric conversion structure on the base material layer, and peeling the base material layer off from the support substrate.

In the above-described method for manufacturing a solar cell, a vertex of the concave-convex structure may be rounded.

In the above-described method for manufacturing a solar cell, the support substrate may be a crystalline silicon substrate, and the concave-convex structure may be an inverted pyramid structure formed by anisotropic etching.

In the above-described method for manufacturing a solar cell, the base material layer at a vertex of the concave-convex structure may have a thickness of 10 μm or less.

In the above-described method for manufacturing a solar cell, the forming the photoelectric conversion structure may include applying a constituent material or a raw material of the constituent material.

In the above-described method for manufacturing a solar cell, the photoelectric conversion structure may include a p-type semiconductor layer, a photoelectric conversion layer, and an n-type semiconductor layer in this order from the base material layer, and the p-type semiconductor layer or the photoelectric conversion layer may be formed by a dipping process.

In the above-described method for manufacturing a solar cell, the p-type semiconductor layer may be constituted of a phosphocarbazole-based material.

In the above-described method for manufacturing a solar cell, the support substrate may include a substrate base material and a blunting layer stacked on a surface of the substrate base material and making a vertex of the concave-convex structure rounded.

In the above-described method for manufacturing a solar cell, a thickness of the blunting layer at the vertex of the concave-convex structure may be greater than a radius of curvature of a surface of the substrate base material at the vertex.

In the above-described method for manufacturing a solar cell, the blunting layer may be thicker at the vertex of the concave-convex structure than on a bottom of a concavity of the concave-convex structure close to the vertex.

In the above-described method for manufacturing a solar cell, the varnish may be a polyamic acid solution or a polyimide solution.

The method for manufacturing a solar cell according to the present disclosure makes it possible to manufacture a solar cell having high photoelectric conversion efficiency.

### BRIEF DESCRIPTION OF THE DRAWINGS

FIG. 1 is a flowchart illustrating a procedure of a method for manufacturing a solar cell according to an embodiment of the present disclosure;

FIG. 2 is a schematic cross-sectional view illustrating a structure of a solar cell manufactured by the method illustrated in FIG. 1;

FIG. 3 is a schematic cross-sectional view illustrating a state in one step of the method illustrated FIG. 1;

FIG. 4 is a partially enlarged cross-sectional view of a support substrate in FIG. 3; and

FIG. 5 is a schematic cross-sectional view illustrating a state in a step of the method illustrated in FIG. 1, subsequent to the step in FIG. 3.

### DETAILED DESCRIPTION

Embodiments of the present disclosure will be described below with reference to the drawings. It should be noted that the hatching, reference signs that denote components, and the like may be omitted for convenience, but in such a case, other drawings will be referred to. The dimensions and the like of various components in the drawings are adjusted for convenience and ease of viewing.

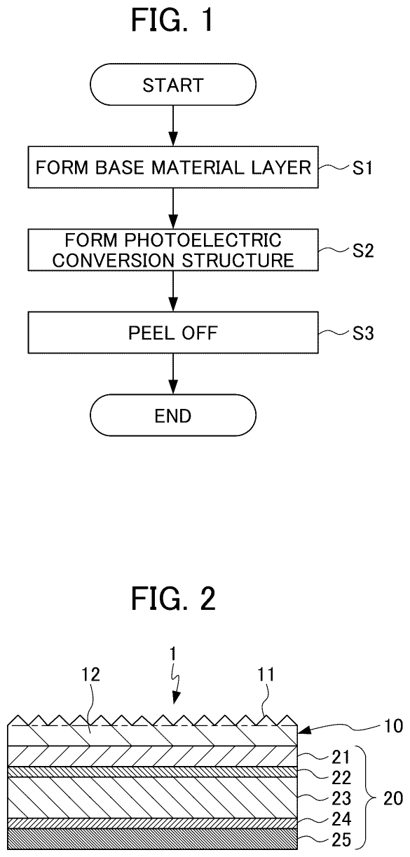

FIG. 1 is a flowchart illustrating a procedure of a method for manufacturing a solar cell according to an embodiment of the present disclosure. FIG. 2 is a schematic cross-sectional view illustrating a structure of a solar cell manufactured by the method illustrated in FIG. 1.

The solar cell 1 manufactured by the method for manufacturing a solar cell according to the present embodiment includes a base material layer 10 disposed on a light-receiving surface side, and a photoelectric conversion structure 20 disposed on a back surface side of the base material layer 10.

The base material layer 10 is a structural member that ensures the strength of the solar cell 1. The base material layer 10 is a transparent flexible resin film. On a light receiving-side surface of the base material layer 10, a texture 11 having minute concavities and convexities for reducing reflectance of light is formed.

In order to reduce the reflection of light, the texture 11 preferably has a shape in which a large number of pyramid-shaped protrusions are spread. In order to reduce reflection of light, the vertexes of the texture 11 preferably have a relatively sharp angular shape. On the other hand, in a case where the concavities of the texture 11 have a sharp angular shape, the base material layer 10 may receive damage such as rupture particularly in a peeling step during the manufacture of the solar cell 1 described later. Therefore, the bottoms of the concavities of the texture 11 are preferably rounded.

A back side region 12 resides from the concavities to the back side of the texture 11 (i.e., the region from the one dot chain line to the back side in FIG. 2) of the base material layer, and the lower limit of the thickness of the back side region 12 is preferably 0.5 μm, and more preferably 1 μm. By making the thickness of the back side region 12 equal to or greater than the lower limit, the mechanical strength of the solar cell 1 can be ensured. The upper limit of the thickness of back side region 12 is preferably 10 μm, and more preferably 8 μm. By making the thickness of the back side region 12 equal to or less than the upper limit, reduction in light absorption rate in the back side region 12 can be achieved in addition to the cost reduction.

In the illustrated solar cell 1 of the embodiment, the photoelectric converting structure 20 is designed to form an invert perovskite solar cell. In the invert perovskite solar cell, the photoelectric conversion structure 20 may include a first electrode layer 21, a p-type semiconductor layer 22, a photoelectric conversion layer 23, an n-type semiconductor layer 24, and a second electrode layer 25 in this order from the base material layer 10. The first electrode layer 21 is a positive electrode for outputting electric power. The first electrode layer 21 is preferably made of a material such as a transparent conductive oxide (TCO) having conductivity and light transmittance. The photoelectric conversion layer 23 generates photocarriers (electrons and holes) by absorbing incident light. The p-type semiconductor layer 22 is a hole transport layer that selectively allows the holes to pass therethrough. The p-type semiconductor layer 22 may be, for example, a self-organized monomolecular film of a constituent material formed of 2PACz ([2-(9H-Carbazol-9-yl)ethyl]phosphonic Acid), MeO-2PACz ([2-(3,6-Dimethoxy-9H-carbazol-9-yl)ethyl]phosphonic Acid), Me-4PACz ([4-(3,6-Dimethyl-9H-carbazol-9-yl)butyl]phosphonic Acid), or the like. The photoelectric conversion layer 23 is a power generation layer that generates photocarriers (electrons and holes) by absorbing incident light. The photoelectric conversion layer 23 may be formed of a material containing a perovskite compound. The n-type semiconductor layer 24 is an electron transport layer that selectively allows electrons to pass therethrough. The n-type semiconductor layer 24 may be made of a fullerene-based material, a tin oxide-based material, bathocuproine, or a laminated film thereof. The second electrode layer 25 is a negative electrode for outputting electric power. The second electrode layer 25 is preferably made of a material mainly containing a metal having low electric resistance. An oxide buffer layer (not shown), a representative example of which is NiOx, may be interposed between the first electrode layer 21 and the p-type semiconductor layer 22. The photoelectric conversion structure 20 may constitute a sub-module that is divided into a plurality of sub-cells when viewed in plan view.

The method for manufacturing a solar cell according to the present embodiment includes a base material layer forming step (Step S1), a photoelectric conversion structure forming step (Step S2), and a peeling step (Step S3).

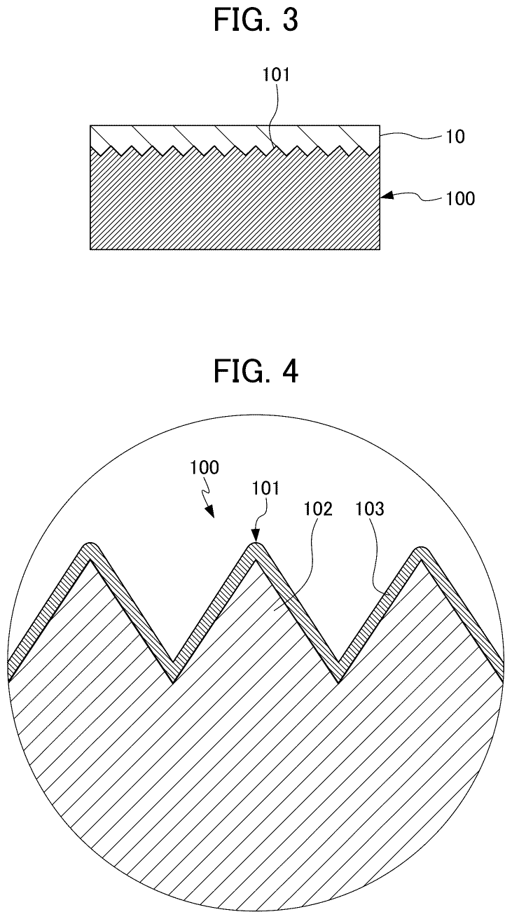

As illustrated in FIG. 3, in Step S1 as the base material layer forming step, the base material layer 10 is formed on a surface of a support substrate 100 by applying varnish to the surface. The support substrate 100 supports an intermediate product under the manufacturing process. The surface of the support substrate 100 (the surface on which the base material layer 10 is formed) is macroscopically flat, and microscopically has a concave-convex structure 101 including a large number of projections. Therefore, the shape of the concave-convex structure 101 is transferred to the surface of the base material layer 10 supported on the support substrate 100, resulting in the formation of the texture 11.

It is preferable to use a crystalline silicon substrate as the support substrate 100. In the case where the support substrate 100 is a crystalline silicon substrate, the concave-convex structure 101 can be formed relatively easily by anisotropic etching. Preferably, the concave-convex structure 101 is an inverted pyramid structure (a structure having quadrangular pyramid-shaped concavities). By forming the concave-convex structure 101 as the inverted pyramid structure, it is possible to form, on the base material layer after the peeling step, the texture 11 having a pyramid structure that takes in a large amount of light by multiple reflection. In addition, the concave-convex structure 101 functions as scaffolding, whereby the adhesion between the support substrate 100 and the base material layer 10 is improved. Therefore, even in a case where the manufacturing process of the solar cell 1 includes a step of immersion in a solution, such as a dipping process, the solution is less likely to penetrate between the support substrate 100 and the base material layer 10, and peeling of the base material layer 10 can be suppressed during the process.

The lower limit of the maximum height Rz (JIS-B0601) of the concave-convex structure 101 is preferably 0.5 μm, and more preferably 0.8 μm. On the other hand, the upper limit of the maximum height Rz of the concave-convex structure 101 is preferably 10 μm, and more preferably 5 μm. Setting the arithmetic average roughness Rz of the concave-convex structure 101 to be equal to or greater than the lower limit makes it possible to accurately transfer the shape of the concave-convex structure 101 to the base material layer 10 and to reduce the reflection on the surface. Setting the arithmetic average roughness Rz of the concave-convex structure 101 to be equal to or less than the upper limit makes it possible to reduce the light absorptance of the base material layer 10 to a relatively low level and to reduce the cost.

As described above, in order to round the bottoms of the concavities of the texture 11, it is preferable that the vertexes of the concave-convex structure 101 are rounded. In addition, in order to prevent the material of the base material layer 10 from remaining in the concavities of the concave-convex structure 101 of the support substrate 100 in and after the peeling step, it is preferable that the concavities of the concave-convex structure 101 also have a slight roundness. For this reason, as illustrated in FIG. 4, the support substrate 100 may include a substrate base material 102 and a blunting layer 103 stacked on a surface of the substrate base material 102 and making the vertexes of the concave-convex structure 101 rounded. While the substrate base material 102 has sharp concavities and convexities that have been formed by performing anisotropic etching or the like, the blunting layer 103 is formed by a process such as CVD or the like on the surfaces of the sharp concavities and convexities, whereby vertexes of the concave-convex structure 101 can be rounded. The thickness of the blunting layer 103 at the vertex of the concave-convex structure 101 is preferably larger than the radius of curvature of the surface of the substrate base material 102 at the same vertex. The blunting layer 103 is preferably thicker at the vertex of the concave-convex structure 101 than on the bottom of concavity of the concave-convex structure 101 close to the vertex.

The present inventor's study demonstrated that in a case where a support substrate 100 included a crystalline silicon substrate as the substrate base material 102, had the concave-convex structure 101 formed by anisotropic etching the substrate base material 102, and was devoid of the blunting layer 103, the radius of curvature of the vertex of the concave-convex structure 101 of the support substrate 100 was 5 nm or less. Therefore, the lower limit of the thickness of the blunting layer 103 is preferably 5 nm, and more preferably 10 nm. On the other hand, if the concavities of the concave-convex structure 101 of the base material layer 10 are excessively rounded, the reflectance of the base material layer 10 increases, and it may be difficult to achieve high solar cell characteristics. Therefore, the upper limit of the thickness of the blunting layer 103 is preferably 500 nm or less, and more preferably 400 nm or less. By making the thickness of the blunting layer 103 equal to or less than the upper limit, reflection on the base material layer 10 can be reduced. It is preferable to form the blunting layer 103 from a stable material that has a higher adhesion strength with respect to the support substrate 100 than the base material layer 10. Examples of the material include oxides typified by silicon oxide and nitrides typified by silicon nitride.

As the varnish to be applied to the surface of the support substrate 100, a polyamic acid solution or a polyimide solution is preferably used. The varnish is applied to the surface of the support substrate, and is baked and peeled off, whereby a thin flexible substrate can be produced. By applying the polyamic acid solution to the support substrate 100 and heating the resultant coating film of the polyamic acid solution, the base material layer 10 that has sufficient strength and flexibility and is made of polyimide having a relatively high light transmittance can be formed. That is, the base material layer forming step preferably includes a step of applying the varnish to the support substrate 100 and a step of heating the varnish coating film on the support substrate 100. The amount of the varnish to be applied is adjusted such that the thickness of the back side region 12, that is, the thickness of the base material layer 10 on the vertexes of the concave-convex structure 101, falls within the above-described range.

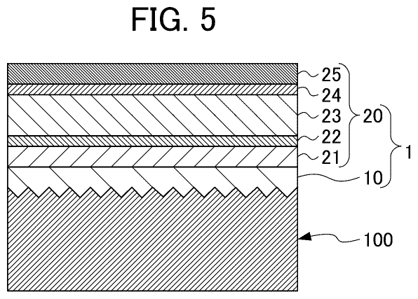

As illustrated in FIG. 5, in Step S2 as the photoelectric conversion structure forming step, the photoelectric conversion structure 20 is formed on the base material layer 10 formed on the surface of the support substrate 100. The photoelectric conversion structure 20 is formed by sequentially stacking the first electrode layer 21, the p-type semiconductor layer 22, the photoelectric conversion layer 23, the n-type semiconductor layer 24, and the second electrode layer 25 by processes appropriate for the respective materials forming these layers. At least one of the p-type semiconductor layer 22, the photoelectric conversion layer 23, or the n-type semiconductor layer 24 can be formed by a process including a step of applying the constituent material (the material that is ultimately required) or a raw material (a precursor or the like) of the constituent material as a dispersion liquid or a solution, or may be formed by a solution growth process in which the constituent material is generated in a raw material solution.

The first electrode layer 21 constituted of a transparent conductive oxide can be stacked by a process such as sputtering or vacuum deposition. The p-type semiconductor layer 22 constituted of a self-organized monomolecular film can be formed by a solution growth process including applying a solution of a phosphocarbazole-based material. Examples of the process for applying such a solution include spin coating and dipping, and the dipping is preferred from the viewpoint of increasing the area. The photoelectric conversion layer 23 containing a perovskite compound can be formed by, for example, a process (two liquid process) in which thin films of different materials are formed by application and drying, and heating is performed to cause these materials to react, a process (poor solvent) in which a solution of a constituent material containing a perovskite compound is applied and crystallized using a poor solvent, or any other process. In the two liquid process, typically, an inorganic layer is formed as a first layer, and thereafter, an organic layer is applied and dried, whereby a perovskite compound is formed. The organic layer can be formed uniformly over a large area by dipping the support substrate 100, on which the layers such as the base material layer 10 and the inorganic layer are formed, in a solution containing the constituent material for the organic layer. In the case of the poor solvent, it is preferable that the support substrate 100 is coated with a solution containing the constituent material containing the perovskite compound, and thereafter, dipped in a solution containing the poor solvent. The n-type semiconductor layer 24 is formed by applying a solution containing a fullerene-based material, a tin oxide-based material, bathocuproine, or the like. The second electrode layer 25 can be formed by forming a layer of a metal by a process such as sputtering, vacuum deposition, or plating. Alternatively, the second electrode layer 25 may be formed by applying and baking a material, such as a silver paste or the like, containing conductive particles and a binder.

In Step S3 as the peeling step, the base material layer 10 is peeled off from the support substrate 100 together with the photoelectric conversion structure 20. In other words, in the peeling step, the solar cell 1 formed on the support substrate 100 is separated from the support substrate 100.

As described above, in the method for manufacturing a solar cell according to the present embodiment, the base material layer 10 is formed by applying the varnish to the support substrate 100 having the concave-convex structure 101 so that the shape of the concave-convex structure 101 is transferred to the base material layer 10, thereby forming the texture 11 that suppresses reflection of incident light to increase the light absorptance and thus improve the photoelectric conversion efficiency of the solar cell 1. In addition, even in the case of employing a step of immersion in a solution such as the dipping process, the solar cell can be processed without peeling.

In the method for manufacturing a solar cell according to the present embodiment, the photoelectric conversion structure 20 is formed on the base material layer 10 formed and held on the support substrate 100. Due to this feature, at the time of forming the photoelectric conversion structure 20, the surface of the base material layer 10 on which the photoelectric conversion structure 20 is formed is maintained flat, making it possible to precisely form the photoelectric conversion structure 20. In particular, in a case where the formation of the photoelectric conversion structure 20 includes a step of applying a material, since the surface to which the material is applied is maintained flat, the resultant coating film has a uniform thickness, whereby the photoelectric conversion structure 20 that achieves high photoelectric conversion efficiency can be formed.

### Examples

Hereinafter, the present disclosure will be specifically described based on examples. However, it should be noted that the present disclosure is not limited to the following examples.

An example was prepared as follows. A crystalline silicon substrate on which inverted pyramid-shaped irregularities were formed by anisotropic etching was used as a substrate base material. A silicon oxide layer was formed by plasma CVD, as a blunting layer having a thickness of 10 nm and stacked on the base material substrate. In this way, a support substrate was produced. A varnish of a polyamic acid solution was applied to the support substrate, whereby a base material layer having a back side region with a thickness of 8 μm was formed. A photoelectric conversion structure is formed on the base material layer, and thereafter, the base material layer is peeled off from the support substrate. As a result, a solar cell having high photoelectric conversion efficiency was successfully produced. Furthermore, a solar cell was prototyped in the same manner except that a support substrate (substrate base material) had no blunting layer stacked thereon. Another solar cell was prototyped in the same manner except that a support substrate had a blunting layer with a thickness of 2 nm formed thereon. In these cases, the base material layer received damage such as rupture when the peeling step was not carefully performed.

Although the embodiments of the present disclosure have been described above, it should be noted that the present disclosure is not limited to the above-described embodiments, and various changes and modifications can be made. For example, the support substrate may be formed of a material other than crystalline silicon, and may be a glass substrate having a surface with a concave-convex structure.

What is claimed is:

1. A method for manufacturing a solar cell, the method comprising:
forming a base material layer on a surface of a support substrate by applying a varnish, the surface having a concave-convex structure;
forming a photoelectric conversion structure on the base material layer, and
peeling the base material layer off from the support substrate.

2. The method for manufacturing a solar cell according to claim 1, wherein
a vertex of the concave-convex structure is rounded.

3. The method for manufacturing a solar cell according to claim 1, wherein
the support substrate is a crystalline silicon substrate, and
the concave-convex structure is an inverted pyramid structure configured by anisotropic etching.

4. The method for manufacturing a solar cell according to claim 1, wherein
the base material layer at a vertex of the concave-convex structure has a thickness of 10 μm or less.

5. The method for manufacturing a solar cell according to claim 1, wherein
the forming the photoelectric conversion structure includes applying a constituent material or a raw material of the constituent material.

6. The method for manufacturing a solar cell according to claim 1, wherein
the photoelectric conversion structure includes a p-type semiconductor layer, a photoelectric conversion layer, and an n-type semiconductor layer in this order from the base material layer, and
the p-type semiconductor layer or the photoelectric conversion layer is configured by a dipping process.

7. The method for manufacturing a solar cell according to claim 6, wherein
the p-type semiconductor layer includes a phosphocarbazole-based material.

8. The method for manufacturing a solar cell according to claim 1, wherein
the support substrate includes a substrate base material and a blunting layer stacked on a surface of the substrate base material and making a vertex of the concave-convex structure rounded.

9. The method for manufacturing a solar cell according to claim 8, wherein
a thickness of the blunting layer at the vertex of the concave-convex structure is greater than a radius of curvature of a surface of the substrate base material at the vertex.

10. The method for manufacturing a solar cell according to claim 8, wherein
the blunting layer is thicker at the vertex of the concave-convex structure than on a bottom of a concavity of the concave-convex structure close to the vertex.

11. The method for manufacturing a solar cell according to claim 1, wherein
the varnish is a polyamic acid solution or a polyimide solution.

12. The method for manufacturing a solar cell according to claim 2, wherein
the support substrate is a crystalline silicon substrate, and
the concave-convex structure is an inverted pyramid structure configured by anisotropic etching.

13. The method for manufacturing a solar cell according to claim 2, wherein
the base material layer at a vertex of the concave-convex structure has a thickness of 10 μm or less.

14. The method for manufacturing a solar cell according to claim 2, wherein
the forming the photoelectric conversion structure includes applying a constituent material or a raw material of the constituent material.

15. The method for manufacturing a solar cell according to claim 2, wherein
the photoelectric conversion structure includes a p-type semiconductor layer, a photoelectric conversion layer, and an n-type semiconductor layer in this order from the base material layer, and
the p-type semiconductor layer or the photoelectric conversion layer is configured by a dipping process.

16. The method for manufacturing a solar cell according to claim 15, wherein
the p-type semiconductor layer includes a phosphocarbazole-based material.

17. The method for manufacturing a solar cell according to claim 2, wherein
the support substrate includes a substrate base material and a blunting layer stacked on a surface of the substrate base material and making a vertex of the concave-convex structure rounded.

18. The method for manufacturing a solar cell according to claim 17, wherein
a thickness of the blunting layer at the vertex of the concave-convex structure is greater than a radius of curvature of a surface of the substrate base material at the vertex.

19. The method for manufacturing a solar cell according to claim 17, wherein
the blunting layer is thicker at the vertex of the concave-convex structure than on a bottom of a concavity of the concave-convex structure close to the vertex.

20. The method for manufacturing a solar cell according to claim 2, wherein
the varnish is a polyamic acid solution or a polyimide solution.
